(19) United States
(12) Patent Application Publication
(10) Pub. No.: US 2003/0081396 A1
(43) Pub. Date: May 1, 2003

(54) Latching mechanism for splice closure

(76) Inventor: Donald J. Smith, Westlake Village, CA (US)

Correspondence Address: BARNES & THORNBURG, 11 South Meridian Street, Indianapolis, IN, 46204, US

(21) Appl. No.: 10/272,265

(22) Filed: Oct. 15, 2002

Related U.S. Application Data
(60) Provisional application No. 60/340,896, filed on Oct. 30, 2001.

(51) Int. Cl. H05K 7/14; H05K 7/18

(52) U.S. Cl. 361/801

(57) ABSTRACT

A splice closure comprising a housing including a top cover, a bottom cover and a latch assembly. The latch assembly including a handle configured to be coupled to the top cover for rotation about a first pivot axis and a bail configured to be coupled to the bottom cover for rotation about a second pivot axis. The bail is configured to be coupled to the handle for rotation about a third pivot axis. The handle is movable between i) a releasing position where the handle is disengaged from the top cover, ii) an intermediate position where the bottom portion of the handle initially engages the top cover for rotation about the first pivot axis and the third pivot axis is on the first side of a plane defined by the first and second pivot axes, and iii) a locking position where the bottom portion of the handle continues to engage with the top cover and the third pivot axis is on the second side of the plane.

### CROSS-REFERENCES TO RELATED APPLICATIONS

This application claims the benefit of U.S. Provisional Patent Application Serial No. 60/340,896, filed on Oct. 30, 2001, and entitled “SPLICE CLOSURE”.

### BACKGROUND AND SUMMARY OF INVENTION

This invention generally relates to a splice closure for protecting cable splices, and more particularly to a latching mechanism for a splice closure.

The telecommunications industry utilizes cables comprising numerous individual conductors, such as copper or fiberoptic conductors. When the cables are strung or laid, it is often necessary to splice sections of these cables. The cables sometimes get damaged during their use due to a variety of factors, such as high wind, storm, snow, etc. Also, individual copper wire or fiberoptic conductors are prone to damage. When they are damaged, it is necessary to splice together the damaged sections of the cables. Typically, a splice closure is positioned around the splices to protect the exposed conductors from the elements, and also to protect the splices from the longitudinal and shear forces.

The prior art is replete with various types of splice closures. An example of a prior art closure can be found in U.S. Pat. No. 6,177,634. The splice closure disclosed therein includes a tubular protective case comprising front and back covers. The left and right ends of the back cover are configured to form integrally therewith left and right half end seals, which are adapted to mate with separately-formed left and right half end seals. The separately-formed left and right half end seals are formed to fit inside the left and right ends of the front cover. The separately-formed left half end seal is secured to the integrally-formed left half end seal, with a first set of cables clamped between the mating surfaces thereof. Likewise, the separately-formed right half end seal is secured to the integrally-formed right half end seal, with a second set of cables clamped between the mating surfaces thereof. The two sets of cables are spliced together and the front cover is bolted in place over the back cover to complete the assembly.

According to the present invention, a splice closure includes a first housing portion, a second housing portion, and a plurality of latch assemblies. The plurality of latch assemblies are configured to secure the first housing portion to the second housing portion to prevent access to the interior region of the splice closure when any one of the plurality of latch assemblies is in a locking position. The first and second housing portions are unlocked to permit access to the interior region when all of the plurality of latch assemblies are in their respective releasing positions.

An illustrative splice closure includes a top cover, a bottom cover and a latch assembly. The top and bottom covers define an interior region when mated together. The latch assembly includes a handle configured to be coupled to the top cover for rotation about a first pivot axis and a bail configured to be coupled to the bottom cover for rotation about a second pivot axis. The bail is configured to be coupled to the handle for rotation about a third pivot axis. The bail is configured to rotate about the second pivot axis when the handle is rotated about the first pivot axis. The handle is movable between i) a releasing position where the handle is disengaged from the top cover, ii) an intermediate position where the bottom portion of the handle initially engages the top cover for rotation about the first pivot axis and the third pivot axis is on the first side of a plane defined by the first and second pivot axes, and iii) a locking position where the bottom portion of the handle continues to engage with the top cover and the third pivot axis is on the second side of the plane.

Additional features of the present invention will become apparent to those skilled in the art upon a consideration of the following detailed description of the following embodiments exemplifying the best mode of carrying out the invention as presently perceived.

### BRIEF DESCRIPTION OF DRAWINGS

The detailed description particularly refers to the accompanying drawings in which:

FIG. 1 is a perspective view of an illustrative splice closure, and showing a top cover, a bottom cover, left and right end caps, and a plurality of latches for securing the top cover to the bottom cover,

FIG. 2 is a top view of the illustrative splice closure,

FIG. 3 is a front view of the illustrative splice closure,

FIG. 4 is a sectional view of the illustrative splice closure along line 4-4 in FIG. 3,

FIG. 5 is a cutaway view of the illustrative splice closure,

FIG. 6 shows a detail identified by a numeral 66 in FIG. 1,

FIG. 7 shows a detail identified by a numeral 68 in FIG. 5,

FIG. 8 shows an enlarged view of a latch handle,

FIG. 9 is a sectional view of the latch handle, and

FIG. 10 is a partial sectional view of a bottom connector integrally formed with the bottom cover, and showing a keyhole-shaped pivot slot formed therein.

### DETAILED DESCRIPTION OF DRAWINGS

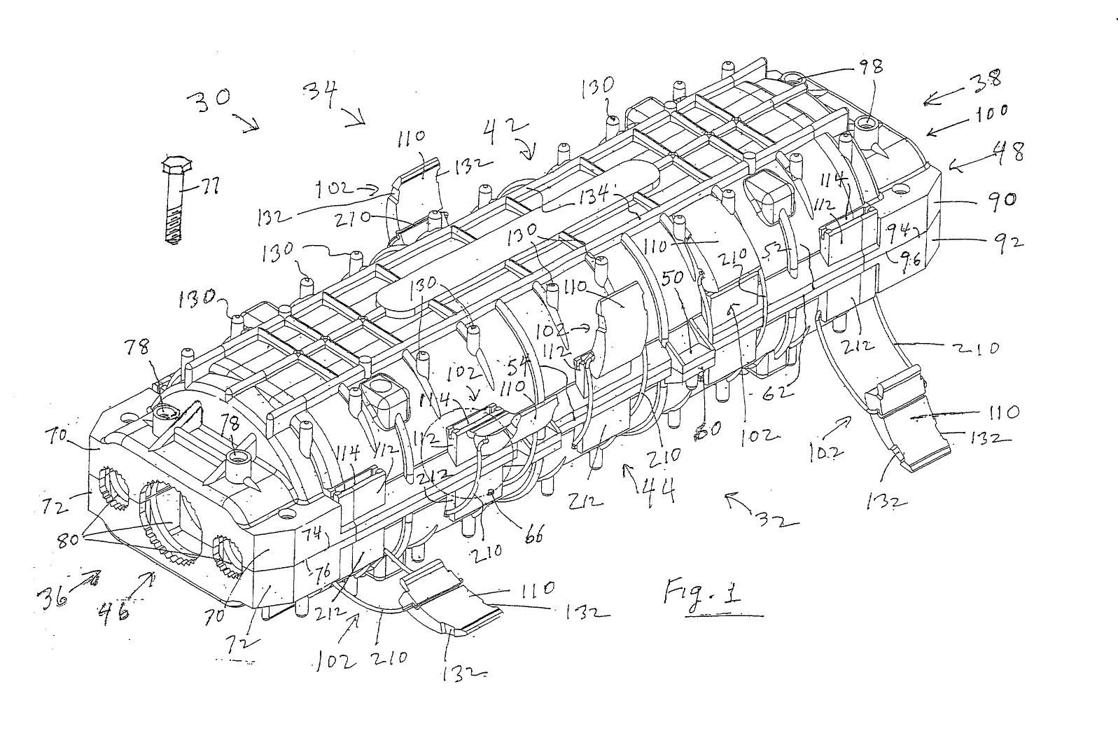

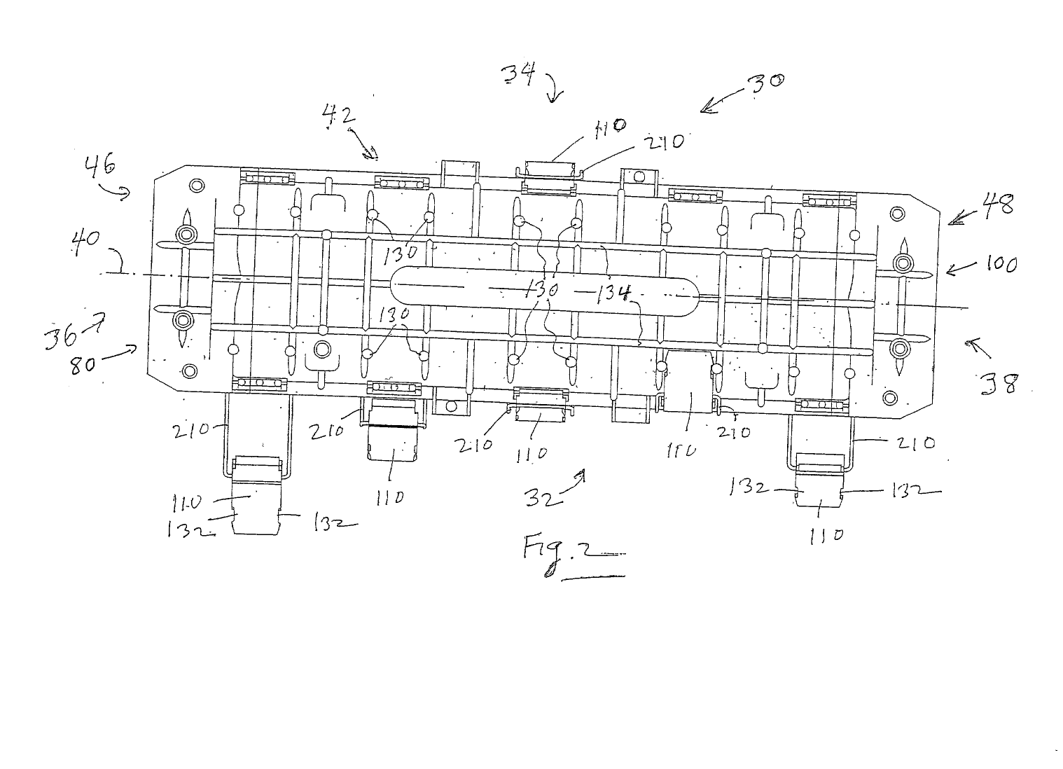

Referring to FIGS. 1-5, an illustrative closure 30 has a front side 32, a rear side 34, a left end 36, a right end 38, and a longitudinal axis 40 (FIGS. 2 and 3). The closure 30 includes a top cover 42, a bottom cover 44, a two-piece left end cap 46 and a two-piece right end plate or cap 48. End caps 46, 48 are sometimes referred herein to as end seals or end plates.

As used in this description, the phrase “front or first side 32” will be used to denote the side of any referred-to object that is positioned to lie nearest the front side 32 of the closure 30, and the phrase “rear or second side 34” will be used to denote the side of any referred-to object that is positioned to lie nearest the rear side 34 of the closure 30. Likewise, the phrase “left or first end 36” will be used to denote the end of any referred-to object that is positioned to lie nearest the left end 36 of the closure 30, and the phrase “right or second end 38” will be used to denote the end of any referred-to object that is positioned to lie nearest the right end 38 of the closure 30.

As shown in FIG. 1, the top and bottom covers 42, 44 each have a generally semicircular transverse cross-section. The front and rear edges of the top cover 42 are configured to form longitudinally-extending flanges 50 and the front and rear edges of the bottom cover 44 are configured to form longitudinally-extending flanges 60. The longitudinally-extending top flanges 50 of the top cover 42 define a downwardly-facing sealing surface 52, and the longitudinally-extending bottom flanges 60 of the bottom cover 44 define an upwardly-facing sealing surface 62. The top and bottom covers 42, 44 meet along their respective sealing surfaces 52, 62 (collectively referred to herein as a longitudinal split plane 54) to form an internal cavity 56 bounded by top and bottom covers 42, 44 and the end caps 46, 48.

The left and right end caps 46, 48 are mirror images of each other, and each have a generally circular cross-section. The left end cap 46 comprises top and bottom half end caps 70, 72 (sometimes referred to herein as top and bottom clamps). The top clamp 70 includes a downwardly-facing sealing surface 74. The bottom clamp 72 is integrally formed with the bottom cover 44, and includes an upwardly-facing sealing surface 76. Two bolts 77 extend through two oversized openings 78 in the top clamp 70, and are screwed into two threaded openings (obscured view) in the bottom clamp 72 to secure the top clamp 70 to the bottom clamp 72. The downwardly-facing sealing surface 74 of the top clamp 70 and the upwardly-facing sealing surface 76 of the bottom clamp 72 are configured to form three cable entry ports or entrances 80 through which up to three cables enter the interior cavity 56 from the left hand side. Blank plugs (not shown) are used to close off unused cable entry ports 80. The sealing surfaces 74, 76 of the top and bottom clamps 70, 72 are generally coplanar with the respective sealing surfaces 52, 62 of the top and bottom covers 42, 44.

Likewise, the two-piece right end cap 48 comprises top and bottom clamps 90, 92 (sometimes referred to herein as top and bottom clamps). The top clamp 90 includes a downwardly-facing sealing surfaces 94. In the illustrated embodiment, the bottom clamp 92 is integrally formed with the bottom cover 44, and includes an upwardly-facing sealing surface 96. Two bolts 77 extend through two oversized openings 98 in the top clamp 90, and are screwed into two threaded openings (obscured view) in the bottom clamp 92 to secure the top clamp 90 to the bottom clamp 92. The downwardly-facing sealing surface 94 of the top clamp 90 and the upwardly-facing sealing surface 96 of the bottom clamp 92 are configured to form three cable entry ports or entrances 100 through which up to three cables enter the interior cavity 56 from the right hand side. Blank plugs (not shown) are used to close off unused cable entry ports 100. The sealing surfaces 94, 96 of the top and bottom clamps 90, 92 are generally coplanar with the respective sealing surfaces 52, 62 of the top and bottom covers 42, 44.

Although the left and right end caps 46, 48 each comprise two portions (top and bottom clamps), they may each comprise three portions (top, middle and bottom clamps). A three-piece construction of the end caps allows a first layer of cables to be clamped between the middle and bottom clamps, and a second layer of cables to be clamped between the top and middle clamps. Thus, cables entering the closure can be clamped down in two steps, simplifying the task of clamping down a large number of cables entering the closure. A three-piece construction of this type is shown and described in detail in a U.S. patent application Ser. No.______ (Attorney Docket No. 5164-71499), entitled “FIBEROPTIC SPLICE CLOSURE”, which is filed on the same day as this application, which is assigned to the same assignee as this patent application, and which is hereby incorporated in its entirety by reference herein.

The left top clamp 70 is dimensioned and configured to fit inside the left end 36 of the top cover 42. Likewise, the right top clamp 90 is dimensioned and configured to fit inside the right end 38 of the top cover 42. Although the illustrated closure 30 is provided with three cable entrances 80, 100 at each end 36, 38, the closure 30 may very well be designed to have a different number of cable entrances. For example, the closure 30 may have three cable entrances at one end and no cable entrances at the other end.

The end sections of the cables are typically wrapped with a strip of sizing tape to make the cables fit tightly in the cable entrances 80, 100. Blank plugs (not shown) are used to close off unused cable entrances 80, 100. As shown, the inside surfaces of the cable entrances 80, 100 are jagged or serrated to prevent axial slippage between the cables and the respective top and bottom clamps 70, 72 and 90, 92, which are securely bolted to the bottom cover 44.

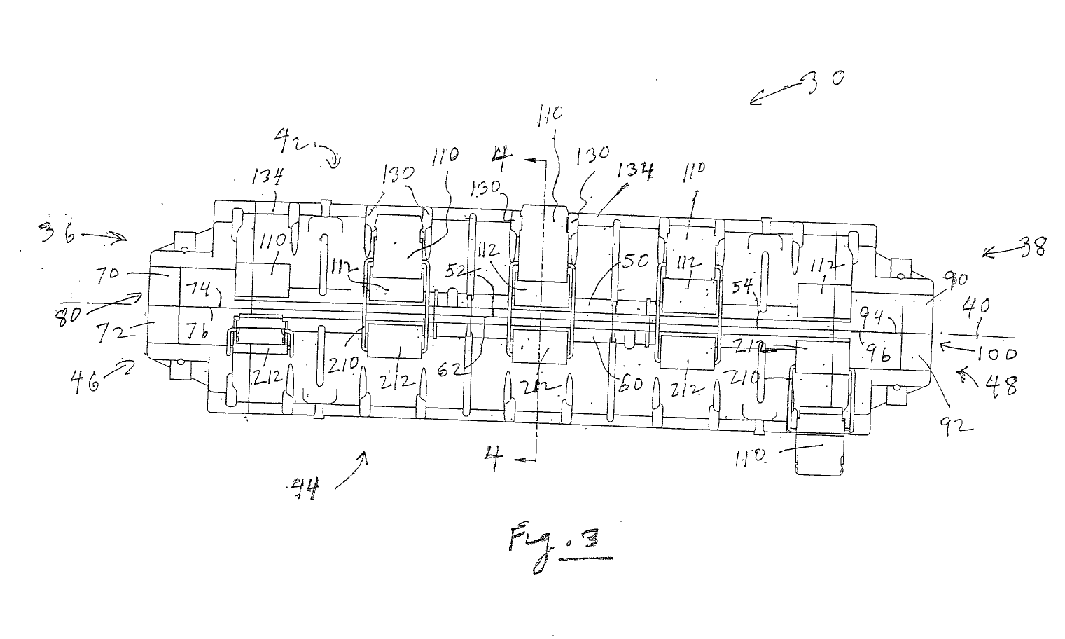

As shown in FIG. 4, a gasket 58 is placed between the longitudinally-extending flanges 50, 60 of the top and bottom covers 42, 44 to form an air tight closure. Additional gaskets 58 are placed around the outer peripheral surfaces of the top clamps 70, 90 to seal the space between the outer peripheral surfaces of the top clamps 70, 90 and the inner peripheral surfaces of the top cover 42. The flanges 50, 60 of the top and bottom covers 42, 44 and the outer peripheral surfaces of the top clamps 70, 90 may be provided with respective longitudinal and circumferential sealing grooves. The gaskets 58 may be provided with complementary beads for reception in the longitudinal and circumferential sealing grooves. The blank plugs (if any), the sizing tape and the gaskets serve to produce an air tight closure to protect the splices from the elements. The closure 30 may include an air valve (not shown) to allow the closure 30 to be pressurized after completing the assembly to make sure that there are no air leaks, and the closure 30 is air tight.

A plurality of latches 102 are used for releaseably securing the top cover 42 to the bottom cover 44 to form an air tight closure. In the illustrated embodiment five latches 102 are used on each side 32, 34 of the closure 30. Referring to FIGS. 1-9, each latch 102 includes a handle 110 (also referred to herein as an actuator or a first latch member) and a loop 210 (also referred to herein as a bail or a second latch member). A top connector 112 (also referred to herein as a handle connector or a handle anchor member) is coupled to the top cover 42 near the top flange 50, and a bottom connector 212 (also referred to herein as a loop connector or a loop anchor member) is coupled to the bottom cover 44 near the bottom flange 60. The connectors 112, 212 are disposed on the opposite sides of the longitudinal split plane 54. Illustratively, the connectors 112, 212 are integrally formed with the top and bottom covers 42, 44. The loop 210 has a generally circular cross-section.

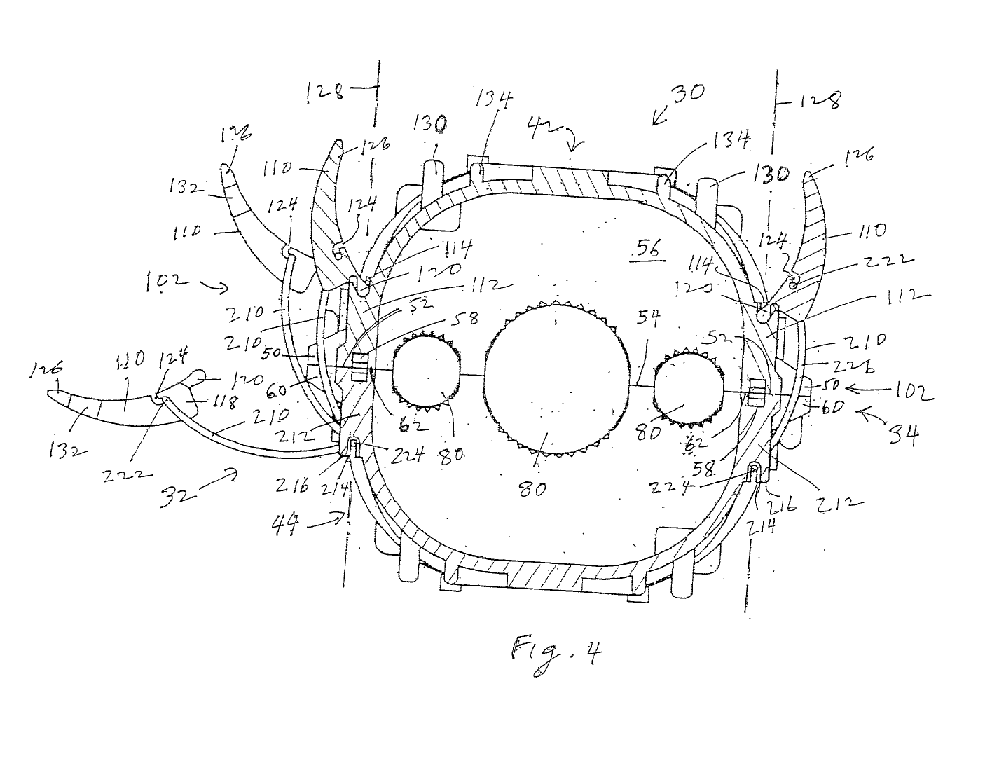

As shown in FIG. 6, the top connector 112 includes a longitudinally-extending pivot slot 114 (also sometimes referred to herein as a pivot axis) at an upper surface 116 thereof. A first end 118 of the handle 110 includes a pivot arm 120 which is configured to be received in the pivot slot 114 in the upper surface 116 of the top connector 112 when the handle 110 is swung from a first position where the handle 110 is disengaged from the top connector 112 (the first position is sometimes referred to herein as a disengaged position or an out-of-the-way position) to a second position where the pivot arm 120 is received in the pivot slot 114 and the handle 110 is in an open position (the second position is sometimes referred to herein as an engaged open position). The pivot slot 114 and the pivot arm 120 are both provided with rounded engaging surfaces to facilitate rotation of the handle 110 from the second position where the pivot arm 120 is received in the pivot slot 114 and the handle 110 is in an open position to a third position where the handle 110 is laid against the top cover 42 to securely lock the top cover 42 to the bottom cover 44 (the third position is sometimes referred to herein as an engaged closed or latched position). As shown in FIG. 4, the handle 110 is curved at a matching radius to the body of the closure 30 to allow its flush laydown in the closed position.

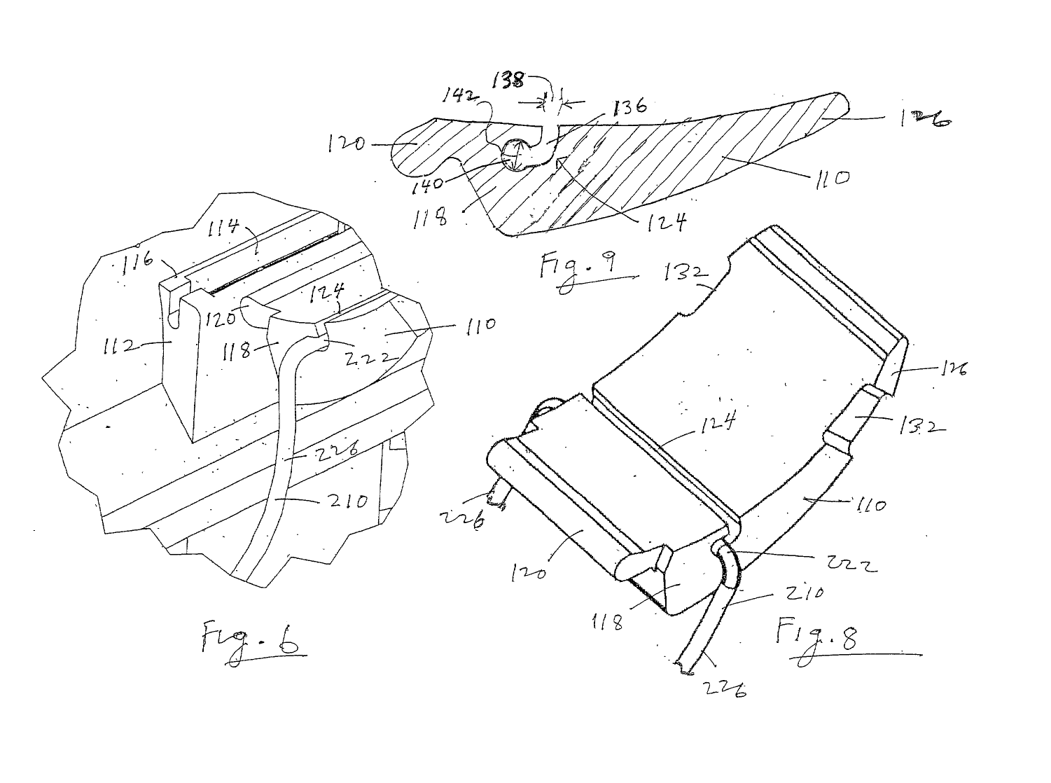

A middle or intermediate portion of the handle 110 is formed to include a longitudinally-extending pivot slot 124 (also sometimes referred to herein as a pivot axis). The pivot slot 124 is sized to receive an upper portion 222 of the loop 210. As shown in FIG. 9, the pivot slot 124 has a keyhole-shaped cross section (i.e., a narrow section followed by a rounded section) to allow the upper portion 222 of the loop 210 to snap into place. The keyhole-shaped pivot slot 124 retains the upper portion 222 of the loop 210 in normal use, while allowing its easy removal for repair or replacement, if necessary. Also, the pivot slot 124 is doglegged or L-shaped, as shown, to prevent the upper portion 222 of the loop 210 from accidently slipping out of the slot 124 when the handle 110 is moved from the open position to the closed position.

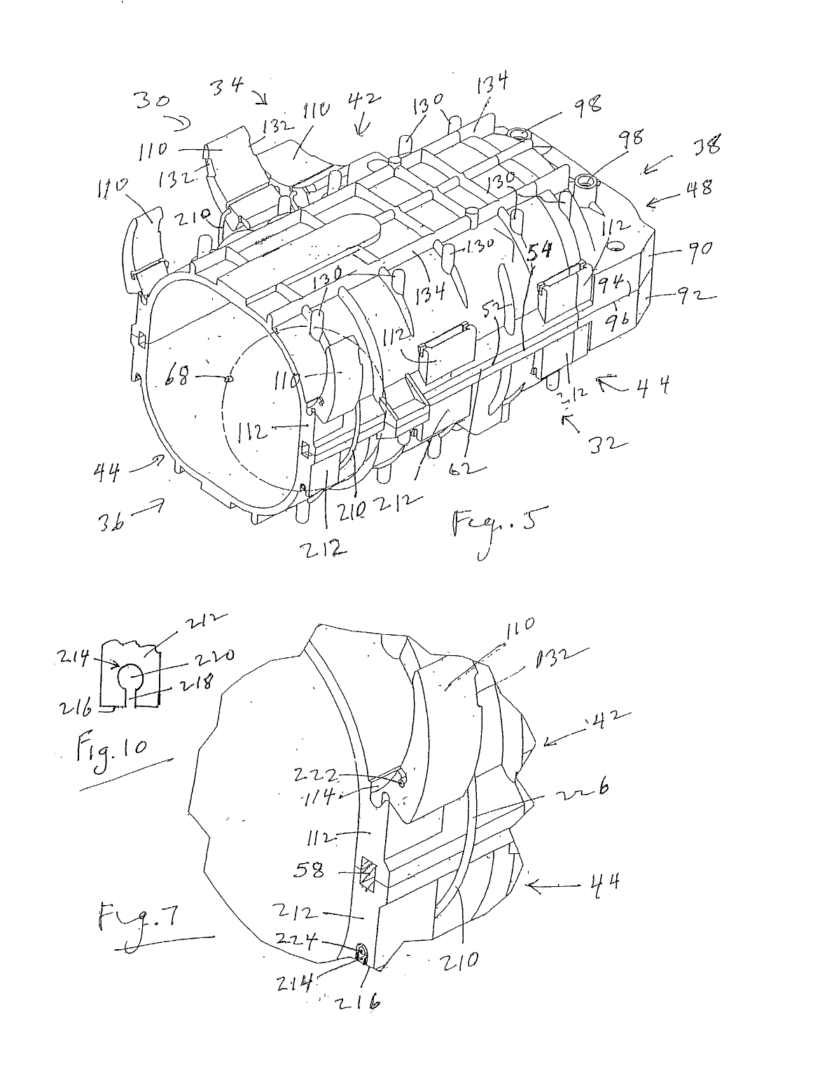

Likewise, as shown in FIG. 7, the bottom connector 212 includes a longitudinally-extending pivot slot 214 (also sometimes referred to herein as a pivot axis) at a lower surface 216 thereof. The pivot slot 214 is sized to receive a lower portion 224 of the loop 210. The pivot slot 214 has a keyhole-shaped cross section (i.e., a narrow section followed by a rounded section) as shown in FIG. 10 to allow the lower portion 224 of the loop 210 to snap into place. The keyhole-shaped pivot slot 214 retains the lower portion 224 of the loop 210 in normal use, while allowing its easy removal for repair or replacement, if necessary. As illustrated, the loop 210 includes opposite side arms 226 extending between the upper and lower portions 222, 224 thereof. The side arms 226 are spaced apart so that the side arms 226 straddle the top and bottom connectors 112, 212 when the handle 110 is in the closed position.

In operation, an upper end 126 of the handle 110 is first moved from the out-of-the-way position where the handle 110 is disengaged from the top connector 112 to the engaged open position where the pivot arm 120 is received in the pivot slot 114 in the upper surface 116 of the top connector 112. The upper end 126 of handle 110 is then moved from the open position to the closed position where the handle 110 is laid flush against the top cover 42. This draws the top and bottom covers 42, 44 together and compresses the gasket 58. The loop 210 is curved to match the radius of the body of the closure 30 to allow the handle 110 to be moved to the closed position without interference from the loop 210. This also allows the clamping force exerted by the closed latch 102 to be directly above and below the gasket 58, thereby uniformly distributing the clamping force on the gasket 58.

As the upper end 126 of the handle 110 is moved from the open position to the closed position, the pivot slot 124 in the handle 110 moves from outside of a plane 128 passing through the top pivot slot 114 in the upper surface 116 of the top connector 112 and the bottom pivot slot 214 in the lower surface 216 of the bottom connector 212 to the inside of the plane, thereby biasing the handle 110 toward its closed position. Thus, the handle 110 goes over the center as it moves from the open position to the closed position, and remains in the closed position until a technician deliberately opens it. The top cover 42 includes two opposed locking pins 130 that are dimensioned and positioned to be snapped into two opposed notches 132 in the handle 110 adjacent to the upper end 126 thereof. In addition, when the handle 110 is moved to the closed position, the upper end 126 of the handle 110 is flush with a rib 134 in the top cover 42. These features provide security against accidental or frivolous opening of the latch 102. It is necessary to use a screwdriver or a similar tool to pry open the latch 102.

As shown in FIG. 9, the longitudinally-extending pivot slot 124 in the intermediate portion of the handle 110 has a first narrow passageway 136 having a width dimension 138 smaller than the diameter of the loop 210. The pivot slot 124 has a second cylindrical portion 140 sized to rotatably receive the top portion 222 of the loop 210. In some embodiments, the second cylindrical portion 140 may be slightly over-sized to allow free rotation of the top portion 222 of the loop 210. As previously indicated, the doglegged narrow passageway 136 prevents the top portion 222 of the loop 210 from accidently slipping out of the pivot slot 124 when the handle 110 is moved from the open position to the closed position.

Likewise, as shown in FIG. 10, the longitudinally-extending pivot slot 214 in the bottom surface 216 of the second connector 212 has a keyhole-shaped cross section to prevent the bottom portion 224 of the loop 210 from accidently slipping out of the pivot slot 214 when the handle 110 is moved from the open position to the closed position. As shown, the pivot slot 214 has a first narrow passageway 218 having a width dimension smaller than the diameter of the loop 210. The pivot slot 214 has a second cylindrical portion 220 sized to rotatably receive the bottom portion 224 of the loop 210.

Illustratively, the materials used for the closure 30 are as follows: 1) the top and bottom covers 42, 44—glass-filled polypropylene, 2) the left and right end caps 46, 48—glass-filled polypropylene, 3) the sizing tape 56—Neoprene, 4) the gaskets 58—silicone-based rubber or Neoprene, 5) the loop 210—Stainless steel wire, and 6) the handle 110—Nylon or ABS. Illustratively, the dimensions of the closure 30 are as follows: 1) the top cover 42—22 inches long×8 inches wide×3.5 inches high, 2) the bottom cover 44—28 inches long×8 inches wide×3.5 inches high, 3) the inside diameter of the closure 30—6.8 inches, 4) the nominal outside diameter of the closure 30—7.2 inches, 5) the outside diameter of the closure 30 at a maximum point—7.5 inches, 6) large diameter cable entrances 80, 100—2.8 inches, 7) small diameter cable entrances 80, 100—1.4 inches, 8) the loop 210—0.125 inch diameter, 9) the dimension 138 of the L-shaped slot 124 in the handle 110—0.115 inches, and 10) the dimension 142 of the L-shaped slot 124 in the handle 110—0.125 inches.

Although the present invention has been described in detail with reference to certain preferred embodiments, variations and modifications exist within the scope and spirit of the present invention as described above.

1. A splice closure comprising:
a first housing portion,
a second housing portion,
the first housing portion being configured to mate with the second housing portion to form an interior region,
a plurality of latch assemblies releasably coupled to the closure, each latch assembly being movable between a locking position and a releasing position, the first and second housing portions being locked to prevent access to the interior region when any one of the plurality of latch assemblies is in the locking position, and the first and second housing portions being unlocked to permit access to the interior region when all of the plurality of latch assemblies are in the releasing positions.

2. The closure of claim 1, wherein each latch assembly comprises:
a first latch member having a top portion, a bottom portion and an intermediate portion extending between the top and bottom portions thereof, the bottom portion of the first latch member being configured to be coupled to one of the first and second housing portions for pivoting movement about a first pivot axis,
a second latch member having a top portion, a bottom portion and an intermediate portion extending between the top and bottom portions, the bottom portion of the second latch member being configured to be coupled to the other of the first and second housing portions for pivoting movement about a second pivot axis, the top portion of the second latch member being configured to be coupled to the intermediate portion of the first latch member for pivoting movement about a third pivot axis, the second latch member being configured to rotate about the second pivot axis when the first latch member is pivoted about the first pivot axis, the first and second pivot axes defining a plane, and
the first latch member being movable between a releasing position where the first latch member is disengaged from the one of the first and second housing portions, an intermediate position where the bottom portion of the first latch member initially engages the one of the first and second housing portions for pivoting movement about the first pivot axis and the third pivot axis is on a first side of the plane, and a locking position where the bottom portion of the first latch member continues to engage with the one of the first and second housing portions and the third pivot axis is on a second side of the plane.

3. The closure of claim 2, wherein one of the first and second housing portions is a top cover, wherein the other of the first and second housing portions is a bottom cover, wherein the first latch member is a handle, and wherein the second latch member is a loop, wherein the bottom portion of the handle is configured to be coupled to the top cover for pivoting movement about the first pivot axis, wherein the bottom portion of the loop is configured to be coupled to the bottom cover for pivoting movement about the second pivot axis, and wherein the top portion of the loop is configured to be coupled to the intermediate portion of the handle for pivoting movement about the third pivot axis.

4. The closure of claim 3, wherein the closure has a longitudinal axis, wherein the first, second and third axes extend generally parallel to the longitudinal axis of the closure.

5. The closure of claim 4, including a first connector coupled to the top cover, and a second connector coupled to the bottom cover, wherein the loop has spaced-apart side portions that straddle the first and second connectors when the handle is moved to the locking position.

6. The closure of claim 5, wherein the handle is movable between a releasing position where the handle is disengaged from the first connector, an intermediate position where the bottom portion of the handle initially engages the first connector for pivoting movement about the first pivot axis and the third pivot axis is on the first side of the plane, and a locking position where the bottom portion of the handle continues to engage with the first connector and the third pivot axis is on the second side of the plane.

7. The closure of claim 6, wherein the first connector is integrally formed with the top cover, and wherein the second connector is integrally formed with the bottom cover.

8. The closure of claim 7, wherein the top and bottom covers have sealing surfaces which abut when the two covers are mated to form the interior region, wherein the first connector is located above the sealing surface of the top cover, and wherein the second connector is located below the sealing surface of the bottom cover.

9. The closure of claim 8, wherein the first connector includes a longitudinally-extending pivot slot in a top surface thereof which is sized to receive the bottom portion of the handle for rotation about the first pivot axis, wherein the second connector includes a longitudinally-extending pivot slot in a bottom surface thereof which is sized to receive the bottom portion of the loop for rotation about the second pivot axis, and wherein the intermediate portion of the handle includes a longitudinally-extending pivot slot which is sized to receive the top portion of the loop for rotation about the third pivot axis.

10. The closure of claim 9, wherein the loop has a generally circular cross-section having a given diameter, wherein the longitudinally-extending pivot slot in the bottom surface of the second connector includes a first narrow passageway having a width dimension smaller than the diameter of the loop and a second cylindrical portion sized to rotatably receive the bottom portion of the loop.

11. The closure of claim 9, wherein the loop has a generally circular cross-section having a given diameter, wherein the longitudinally-extending pivot slot in the intermediate portion of the handle includes a first narrow passageway having a width dimension smaller than the diameter of the loop and a second cylindrical portion sized to rotatably receive the top portion of the loop.

12. The closure of claim 11, wherein the first narrow passageway of the longitudinally-extending pivot slot in the intermediate portion of the handle has a generally right angle bend to prevent the top portion of the loop from accidentally slipping out of the pivot slot.

13. A splice closure comprising:
a housing including a top cover and a bottom cover, the top and bottom covers when mated together defining an interior region, and
a latch assembly comprising:
a first connector coupled to the top cover,
a handle configured to be coupled to the first connector for pivoting movement about a first pivot axis,
a second connector coupled to the bottom cover, and
a bail configured to be coupled to the second connector for pivoting movement about a second pivot axis,
the bail being configured to be coupled to the handle for pivoting movement about a third pivot axis,
the bail being configured to rotate about the second pivot axis when the handle is pivoted about the first pivot axis, the first and second pivot axes defining a plane, and the handle being movable between a releasing position where the handle is disengaged from the first connector, an intermediate position where the bottom portion of the handle initially engages the first connector for pivoting movement about the first pivot axis and the third pivot axis is on the first side of the plane, and a locking position where the bottom portion of the handle continues to engage with the first connector and the third pivot axis is on the second side of the plane.

14 A splice closure comprising
a housing having a first housing portion and a second housing portion, the first and second housing portions when mated together defining an interior region of the housing, and
a latch assembly having a handle configured to be coupled to the first housing portion for pivoting movement about a first pivot axis, a bail configured to be coupled to the handle for pivoting movement about a second pivot axis, and a catch affixed to the second housing portion, the catch having a catch surface, the bail being configured to engage the catch surface to rotate about a third pivot axis when the handle is pivoted about the first pivot axis, the first and third pivot axes defining a plane, the handle being pivotable about the first pivot axis between a releasing position in which the bail is disengaged from the catch, an intermediate position in which the bail initially engages the catch surface for rotation about the third pivot axis and the second pivot axis is situated on a first side of the plane, and a locking position in which the bail continues to engage with the catch surface and the second pivot axis is situated on a second side of the plane.
